(19) United States
(12) Patent Application Publication
(10) Pub. No.: US 2008/0153266 A1
(43) Pub. Date: Jun. 26, 2008

(54) METHOD TO IMPROVE THE SELECTIVE EPITAXIAL GROWTH (SEG) PROCESS

(75) Inventors: Frederik Leys, Gent (BE); Roger Loo, Kessel-Lo (BE); Matty Caymax, Leuven (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Interuniversitair Microeletronica Centrum (IMEC) VZW, Leuven (BE)

(21) Appl. No.: 11/962,020

(22) Filed: Dec. 20, 2007

(30) Foreign Application Priority Data
Dec. 21, 2006 (EP) 06126942.9
Jul. 20, 2007 (EP) 07112851.6

(51) Int. Cl. H01L 21/20

(52) U.S. Cl. 438/479; 257/E21.09

(57) ABSTRACT

A method of producing a semiconductor device using a selective epitaxial growth (SEG) process is disclosed. In one aspect, the method comprises providing a semiconductor substrate, forming a pattern of an insulation material on the semiconductor substrate, thereby defining a covered and non covered surface, performing a cleaning processing of the covered and non covered surface of the substrate having the insulating pattern defined, loading the substrate with the insulating pattern into a reaction chamber of an epitaxial reactor, and starting a selective epitaxial growth comprising an injection of at least one semiconductor source gas possibly with at least one first carrier gas in the reaction chamber of the epitaxial reactor. The method further comprises, prior to the selective epitaxial growth, the surface of the substrate is subjected in the reaction chamber to an in situ pre-treatment with the injection of a halogen containing etching gas possibly with a second carrier gas.

### BACKGROUND OF THE INVENTION

1. Field of the Invention

The present invention is related to the field of semiconductor devices and the production thereof using methods of selectively forming epitaxial semiconductor layers.

More precisely, the present invention is related to improved methods for producing a semiconductor device using a selective epitaxial growth.

2. Description of the Related Technology

Epitaxial growth is the process of depositing a thin layer (typically 0.5 to 20 microns) of single crystal material over a single crystal substrate, usually through chemical vapor deposition (CVD). Epitaxial growth is defined by some degree of matching between the crystalline structure of the grown/deposited layer and the crystalline structure of the substrate.

Semiconductor manufacturing widely uses CVD to deposit materials in various forms. For example in the semiconductor industry, CVD is a chemical process used to produce thin films of high-purity and high-performance solid materials. In a typical CVD process, the substrate is exposed to one or more volatile precursors (semiconductor source gasses) which react and/or decompose on the substrate surface to produce the desired thin film of the required material.

Low-temperature epitaxial depositions are very attractive in device fabrication to improve electrical performances of advanced complementary metal oxide semiconductors (CMOS) and bicomplementary metal oxide semiconductors (BiCMOS). CMOS is a major class of integrated circuits covering both digital logic and analog circuits.

In particular, Selective Epitaxial Growth (SEG) of silicon, silicon-germanium, pure germanium and III/V's such as GaAs and InGaAs plays an important role in the manufacturing of the very large scale integrated (VLSI) and the ultra large scale integrated (ULSI) circuits using three-dimensional bipolar, metal oxide semiconductors (MOS), bicomplementary metal oxide semiconductors (BiCMOS) and silicon-on-insulator (SOI) devices. Given a semiconductor substrate with a patterned structure defined in an insulating/dielectric mask material SEG is a process in which the epitaxial growth of a semiconductor material occurs only on the exposed (non-covered) areas of the semiconductor substrate. The process is called ‘selective’ if no deposition/growth occurs on the areas covered with the insulator/dielectric mask. This technique has attracted considerable interest due to its potential for self aligned processing of very advanced devices. Some important applications of SEG are (i) the base layer stack in Heterojunction Bipolar Transistors in BiCMOS technology; (ii) Raised Source/Drain areas on bulk Si as well as on silicon-on-insulator (SOT) wafers; (iii) growth of Ge on Si or on Shallow Trench Isolation (STI) patterned Si wafers; (iv) growth of III/V on Ge or on STI patterned wafers. STI is an integrated circuit structure which prevents electrical current leakage between adjacent semiconductor device components.

SEG has been used for various deposition chemistries which can be divided into two classes, i.e. with and without the use of chlorine. Typically, unlimited SEG in chlorine free ambient is only possible for temperatures above 1100° C. Below this temperature invariably nucleation of Si on the insulator surface followed by poly-Si deposition will occur. Polysilicon deposition is the process of depositing a layer of polycrystalline silicon on a substrate.

Selectivity of the SEG process (which means that during the SEG the material is grown/deposited on the bare substrate but not on the insulator/dielectric material) at lower temperatures has only been shown in chlorine mixtures containing e.g. SiH4 and HCl, or SiH2Cl2 (DCS) with or without HCl, in which the chlorine component is able to etch away possible nuclei from the insulator surface before they can reach a critical size. In the case of absence of Si nucleation on the insulator surface, selectivity will be enhanced.

But, as underlined by Caymax et al. in the Proceedings of the 206^{th} Meeting of the Electrochemical Society (Abs 1363, 2004), even with chlorine based chemistries full selectivity is not always guaranteed. In order to suppress Si nucleation, an etching gas (e.g. HCl) is added to the semiconductor source gas/precursor.

Etching is used in microfabrication to chemically remove layers from the surface of a wafer during manufacturing.

It is known that variations in previous processing (being e.g. variations in concentration of the chemical used during the wet cleaning process, variation in composition/stoichiometry of the deposited nitride layer material, contamination in general (moisture, organic, metals) originating from the wet chemistry or from the carrier gasses and process gasses) as well as variations in the composition of the insulator can lead to a selectivity loss. Any defects, contamination or irregularities on the insulator surface can induce Si nucleation. In order to compensate for the enhanced Si nucleation, higher flows of the etching gas might be needed, which at their turn have a negative effect on the growth rate and make the control of the process with respect to other unwanted effects (e.g. faceting) very difficult. This can cause important problems, especially in manufacturing.

Thus, as selectivity of the SEG process is influenced by the choice of the insulator material, the way this is deposited and by the processes prior to SEG, it can be desirable to provide a SEG process which is more robust towards variations in the processes prior to SEG and towards contaminations.

### SUMMARY OF CERTAIN INVENTIVE ASPECTS

Certain inventive aspects relate to an improved method, which does not present the drawbacks of prior art techniques, to produce a semiconductor device using a selective epitaxial growth.

In particular, certain inventive aspects deal with the strong restriction on thermal budget of the SEG process for deep sub micron CMOS.

Certain inventive aspects provide a method of surface treatment of the semiconductor substrate, which renders a less reactive surface and, as such, maintains a broader process window for the selective epitaxial process.

Certain inventive aspects provide an improved method to give room for tuning with respect to faceting or to the difference in growth rate on n-type versus p-type implanted substrates.

Certain inventive aspects provide a method for improving the characteristics, i.e. enhancing the selectivity, of the selective epitaxial growth process.

Certain inventive aspects more particularly provide a method for producing a semiconductor device using a selective epitaxial growth (SEG) process comprising:

providing a semiconductor substrate;

forming a pattern of an insulation material on the semiconductor substrate, thereby defining a covered and non covered surface;

loading the substrate with the insulating pattern into a reaction chamber of an epitaxial reactor;

starting a selective epitaxial growth comprising an injection of at least one semiconductor source gas possibly with at least one first carrier gas in the reaction chamber of the epitaxial reactor.

According to one inventive aspect, the process is characterized by the fact that prior to starting the selective epitaxial growth process, the surface of the substrate is subjected in the reaction chamber to an in situ pre-treatment with the injection of a halogen containing etching gas, possibly with a second carrier gas.

According to one inventive aspect, prior to the process of loading the substrate in an epitaxial reactor, the substrate is submitted to a cleaning process.

In one aspect, the cleaning process comprises a wet clean treatment and/or a wet etch treatment.

The semiconductor substrate may be selected from the group consisting of a single crystalline silicon substrate, a single crystalline germanium substrate, a single crystalline silicon germanium substrate, a single crystalline silicon germanium carbide substrate, a single crystalline silicon carbide substrate or a silicon-on-insulator (SOI) substrate.

The insulation material may be a dielectric material, such as silicon dioxide (SiO2) or silicon nitride (Si3N4).

The main semiconductor source gas may be selected from the group consisting of a silicon source gas, a germanium source gas, a silicon germanium source gas, a III/V source gas, a carbon source gas or a source gas selected from the group of germyl-silane gasses or a mixture thereof.

The halogen containing gas may be a F or Cl containing gas and more preferably a Cl containing gas such as a HCl gas, a Cl2 gas, a diluted HCl gas, a diluted Cl2 gas or any other fluor-containing gas or a mixture thereof.

The first and/or second carrier gasses may be a H2 gas or an inert gas.

According to one aspect, the injection of the halogen containing etching gas is at least once performed prior to the injection of the at least one semiconductor source gas; the injection of the halogen containing etching gas is continued without interruption while performing the injection of the at least one semiconductor source gas.

According to another aspect, the injection of the halogen containing etching gas is at least once performed prior to the injection of the at least one semiconductor source gas; the injection of the halogen containing etching gas is stopped and resumed with performing the injection of the at least one semiconductor source gas.

According to another aspect, both the injection of the at least one semiconductor source gas and the injection of the halogen containing etching gas are performed repeatedly.

The in situ pre-treatment with the halogen containing etching gas performed prior to the selective epitaxial growth process may be preceded by an in situ H2 thermal anneal.

The temperature of the in situ H2 thermal anneal may be higher than the temperature of the in situ pre-treatment with the halogen containing etching gas.

The in situ H2 thermal anneal may be performed at a temperature range between about 700° C. and 900° C. and more preferably between about 700° C. and 850° C.

According to one aspect, the temperature of the in situ pre-treatment with the halogen containing etching gas is higher than the temperature of the selective epitaxial growth process.

According to one aspect, the temperature of the in situ pretreatment with the halogen containing etching gas is lower than the temperature of the selective epitaxial growth process.

The selective epitaxial growth process may be performed at a temperature comprised within the range of about 500 to 900° C.

The selective epitaxial growth may be performed either at reduced pressure (LPCVD) or at atmospheric pressure.

The in situ pre-treatment with the halogen containing etching gas may be performed at a temperature comprised between the range of about 500 to 900° C. and more preferably within the range of about 550 to 750° C.

The temperature of the in situ pre-treatment with the halogen containing etching gas may be lower than about 900° C.

The minimum duration of the in situ pre-treatment with the halogen containing etching gas may be at least about 1 second and more preferably at least about 1 minute.

The in situ pre-treatment with the halogen containing etching gas may be performed during at least about 30 seconds and more preferably during a period of time comprised between about 1 and 10 minutes, preferably comprised between about 1 and 8 minutes, and more preferably between about 2 and 4 minutes.

The temperature and the duration of the treatments may be specified in order that the amount of etching required during the in situ pre-treatment with the halogen containing etching gas is less then or equivalent to the etching of about 0.5 to 10 Å of semiconductor material.

In one aspect, during the pre-treatment less than 10 Angstrom and more preferred less than about 5 Angstrom of semiconductor material may be removed from the non covered surface.

### DEFINITIONS

The word “in situ” as used in the present description means inside the reaction chamber of the epitaxial reactor.

“Insulating” as used in the present description is the property of preventing the passage of electricity by surrounding with a nonconductive material.

The term “insulator” as used in the present description is a material that insulates, i.e. a nonconductor of electricity.

A “dielectric” material as used in the present description means a nonconductor of electricity.

It is to be understood that in the present description, the terms “insulator” and “dielectric” are equivalent.

The word “injection” as used in the present description means the act of starting to inject a gas and continuing this injection during a certain time interval.

It is to be understood that a time interval is defined by a definite start and end time.

### BRIEF DESCRIPTION OF THE DRAWINGS

FIG. 1 is describing the process sequence with an in situ (HCl) pre-treatment prior to the injection of the semiconductor source gas in the reaction chamber wherein processes III-V are performed in the epi-reactor.

FIG. 2 is describing the summary of the time schedule for different embodiments of the present invention.

FIG. 3 is representing the measurements of the haze according to different HCl in situ pre-treatment times.

### DETAILED DESCRIPTION OF CERTAIN EMBODIMENTS

Certain embodiments will be further described in detail, making use of non-limiting examples and drawings.

In one aspect the present invention is directed to a method of fabricating a semiconductor device such as a CMOS device. A non-single crystalline pattern is formed on a single crystalline semiconductor substrate. In the case of a CMOS, an insulating spacer is formed on side walls of the non-single crystalline semiconductor pattern.

A surface of the substrate having the insulating spacers defined may be cleaned and subjected to a wet etch treatment in order to remove the native oxide prior to introduction in the reaction chamber. This treatment which is a cleaning and/or wet etch treatment is needed immediately prior to the epitaxial growth, as native oxide is growing on the (bare) substrate when exposed to ambient atmosphere.

The wet etch treatment, e.g. a dilute HF process, enhances the reactivity of the insulating material, leading to a selectivity loss during the selective epitaxial growth. After clean (wet etch) treatment the substrate with the insulating spacer(s) is loaded into the reaction chamber of an epitaxial apparatus.

A first anneal process is then optionally applied to the substrate. The anneal process is performed by injecting a carrier gas in the reaction chamber. Hydrogen may be employed as a carrier gas and the annealing process is preferably performed at a temperature between about 700° C. and 900° C.

Next, after the anneal process is finished, an in situ pretreatment with an etching gas is performed. The etching gas is injected in the reaction chamber prior to the injection of the semiconductor source gas, thereby compensating for the enhanced reactivity of the insulating material. The selective epitaxial growth starts when at least one semiconductor source gas is injected into the reaction chamber. The etching gas may be continuously supplied, without interruption, during the in situ pre-treatment and the selective epitaxial growth, but the flow rates used may be different according to the process.

In one embodiment, the spacers comprise typically a silicon based dielectric material such as silicon oxide or silicon nitride.

In some embodiments, the single crystalline semiconductor substrate may be one of the following substrates: Si, Ge, SiGe, SiGeC and SiC with different compositions or silicon-on-insulator (SOI) substrate.

In other embodiments the non-single crystalline semiconductor dielectric pattern may be formed of an amorphous semiconductor layer or a polycrystalline semiconductor layer. The amorphous semiconductor layer or a polycrystalline semiconductor layer may be a silicon layer, a germanium layer, a silicon germanium layer or a metal gate material.

In other embodiments, the etching gas may contain halogen elements which react with the atoms of the epitaxial semiconductor layer and which are not able to etch the bulk insulator material. Consequently, the in situ treatment will have an effect only on a very thin surface layer of the insulating material. The etching gas containing halogen may be an HCl gas, a Cl2 gas, a diluted HCl or a diluted Cl2 gas. The diluted HCl gas may be a mixture of HCl and H2 gas or a mixture of HCl and an inert gas (e.g. Ar or He). The diluted Cl2 gas may be a mixture of Cl2 and H2 gas or a mixture of Cl2 and an inert gas (e.g. Ar or He).

In a further embodiment, the semiconductor source gas may be one of the silicon source gas, a germanium source gas and a silicon germanium or III/V or mixtures thereof. The silicon source gas may be one of a silane (SiH4) gas, a disilane (Si2H6) gas, a dichlorosilane (SiH2Cl2) gas, a SiHCl3 gas and a SiCl4 gas and the germanium source gas may be a GeH4 gas. The silicon germanium source gas may comprise the silicon source gas and the germanium source gas. The semiconductor source gas may be also one of the more advanced gases from the family of germyl-silanes, e.g. H3GeSiH3, (H3Ge)2SiH2, (H3Ge)3SiH, (H3Ge)4Si or may comprise a carbon source gas for the growth of SiC and SiGeC. The carbon source gas may be C2H6 gas or CH3SiH3 gas. The semiconductor source gas may also contain a doping gas like phosphine (PH3) for n-type doping or diborane (B2H6) for p-type doping.

It is noticed that besides the choice of the insulator material (e.g. SiO₂, Si₃N₄, SiC or a polymeric material) and the way this is deposited, the process processes prior to SEG, like cleaning and diluted HF-dip can have an important influence on the selectivity of the SEG process.

The strong restriction on thermal budget of the selective epitaxial growth process for deep sub micron CMOS processing imposes the use of an HF-dip to remove most of the native oxide prior to deposition. As a negative side-effect, the HF-dip makes the surface of the insulating material more reactive, and this narrows the process window in which the deposition is selective. The enhanced reactivity is observed for insulation material such as silicon nitride and silicon oxide.

In particular in the case of the silicon nitride it is noticed that the cleaning treatment followed by a diluted HF process to remove the native oxide, performed prior to epitaxial growth, make the Si₃N₄ surface more reactive leading to selectivity loss during SEG. More specific, it is observed that on diluted HF treated Si₃N₄ surfaces more nucleation takes place than on the not-cleaned surfaces. The enhanced number of nuclei formed is a direct measure of the reactivity of the surface.

The enhanced reactivity of a nitride surface after HF is observed through the following experiment: a very short deposition is done with dichlorosilane (DCS) on a nitride surface. DCS is a Si precursor gas that is nearly selective without the addition of extra HCl, because it contains Cl. Because the deposition time is very short, only discrete nuclei are formed on the nitride surface instead of closed layers. The number of nuclei formed, for a fixed deposition time, can be counted and it is a direct measure for the reactivity of the surface and of the condition of the reactor gasses and tubes.

Using this method, an increase in the number of nuclei by at least an order of magnitude is observed when the nitride surface is subjected to an HF-dip prior to the DCS deposition.

The enhanced reactivity of nitride is illustrated by the following experiment: 3 silicon wafers are first deposited with 20 nm PECVD nitride and then subjected to a standard SC1 clean, consisting of ammonium peroxide mixture H4OH/H2O2/H2O=1:1:5, followed by DI rinse and drying.

All the wafers are loaded for a short deposition with DCS in the epitaxial (epi) reactor. Prior to the epitaxial growth process, wafers 2 and 3 received an extra HF-dip treatment for 30 sec in HF 2%. Wafer 3 received prior to the DCS deposition an in situ HCl pre-treatment in the epi reactor. Table 1 summarizes the results of the particle measurement before and after the epi deposition in all these cases.

TABLE 1
Particle number before and after deposition measured on LPCVD nitride.

| | | Before deposition | | | | After deposition | | | |
|---|---|---|---|---|---|---|---|---|---|
| | | Bin1 | Bin2 | Bin3 | | Bin1 | Bin2 | Bin3 | |
| | Treatment | LPD > | LPD > | LPD > | Haze | LPD > | LPD > | LPD > | Haze |
| Wafer no | Sequence | 0.100 um | 0.150 um | 0.200 um | (ppm) | 0.100 um | 0.150 um | 0.200 um | (ppm) |
| Wafer 1 | SC1 clean | 253 | 78 | 23 | 0.140 | 3533 | 389 | 32 | 3.419 |
| Wafer 2 | SC1 clean | 229 | 139 | 109 | 0.057 | 69999 | 20802 | 105 | 8.089 |
| | HF-dip | | | | | | | | |
| Wafer 3 | SC1 clean | 252 | 57 | 30 | 0.057 | 48868 | 530 | 63 | 5.980 |
| | HF-dip | | | | | | | | |
| | HCl-preclean | | | | | | | | |

Before deposition all the wafers show similar levels of light point defects (LPD). Their distribution over the different bins (where a bin is referring to a specific range in the particle size distribution based upon the particle diameter) is identical and the haze (being the background scattering information given by a particle measurement tool, which provides a measure of the surface small scale variations, e.g. the presence of small particles with a diameter lower than 50 nm) shows similar values, as can be seen in Table 1. For all the 3 wafers, about 250 counts are measured for bin 1, corresponding to LPD with a diameter higher than 0.1 microns, and the haze show values under 0.15 ppm.

After deposition, the number of LPD in bin 1 is much higher on wafers 2 and 3, which have both undergone a diluted HF-dip before deposition. In case of wafer 2, both bin 1 and bin 2 are saturated and the average haze is about 8.089 ppm, indicating the presence of a high number of small nuclei on the nitride surface.

Wafer 3, which received first a diluted HF-dip followed by an in situ HCl pre-treatment in the epi reactor, prior to the DCS deposition, shows a significant reduction in the number of LPD after deposition: the haze has dropped with about 30% and the bin 2 value (LPD with a diameter>0.150 microns) shows a drop from 20802 to 530, which is actually similar with the value on wafer 1. The enhanced reactivity of the nitride surface was in this case diminished by the in situ HCl pre-treatment.

Therefore it is concluded that an in situ HCl pretreatment prior to SEG process restores the stoichiometry of the nitride top surface layers, initially affected by the diluted HF treatment.

Moreover, the SEG process becomes more robust, since the in situ HCl treatment can compensate for other variations in the process parameters.

For example, values lower than the critical value can be used for the (HCl) etching gas flow added during the SEG process. The critical value refers to a minimum etching gas flow rate needed without in situ HCl pretreatment to have enough selectivity towards nitride. Another advantage of the in situ HCl pretreatment is that by lowering the etching gas (HCl) flow rates it gives more room for tuning the process with respect to faceting or the difference in growth rate on n versus p-type implanted substrates.

At the same time, by introducing the in situ HCl pretreatment, the SEG process becomes more robust towards variability introduced by cleaning, variations in the stoichiometry of the deposited nitride layer, metal or moisture contamination from the carrier gasses/process gasses or from the cleaning bath.

Further, by etching a superficial highly doped layer, a reduction in the difference between the growth rates on n and p-type semiconductor substrates may be achieved.

Most probably a thin oxide layer is present on top of the nitride layer on the as-deposited layer prior to HF-dip, which is actually confirmed by XPS measurements. The thin oxide layer is removed almost completely by the HF-dip, which leads implicit to a selectivity loss during SEG, since it is known that selectivity towards oxide is better than towards nitride.

In one embodiment the process flow comprises:
(I) wet clean, which may be a SC1 clean (commonly known as the first process of the standard RCA clean);
(II) diluted HF treatment (dip), typically 30 sec in HF 2%;
(III) thermal annealing in H2 atmosphere at a temperature between 700-900° C. for 1-10 minutes
(IV) in situ HCl pre-treatment at a temperature between 500-900° C., using flows between with 50-100 sccm HCl flow, diluted in 20-40 slm hydrogen; the etch time may be between 2 and 4 minutes;
(V) selective epitaxial growth by supplying simultaneously an etching gas (e.g. HCl) and at least one source gas (e.g. SiH4, SiCl2H2).

These processes may be consecutive processes.

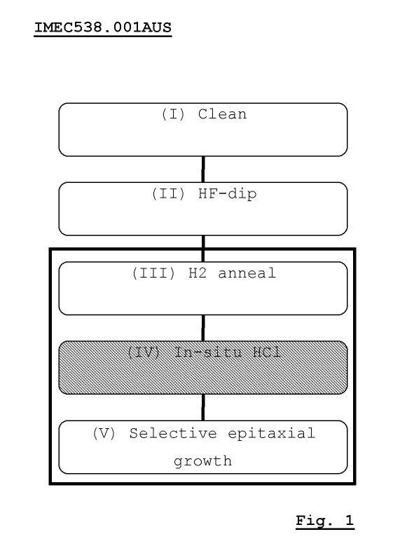

The in situ HCl pre-treatment (process IV in the above scheme and in FIG. 1) is performed prior to the selective epitaxial growth (V) and may be preceded, optionally, by an in situ H2-anneal (III). Processes (I) and (II) are wet processing operations preferably outside the epi-reactor. Processes (III) to (V) are performed in situ in the epi-reactor.

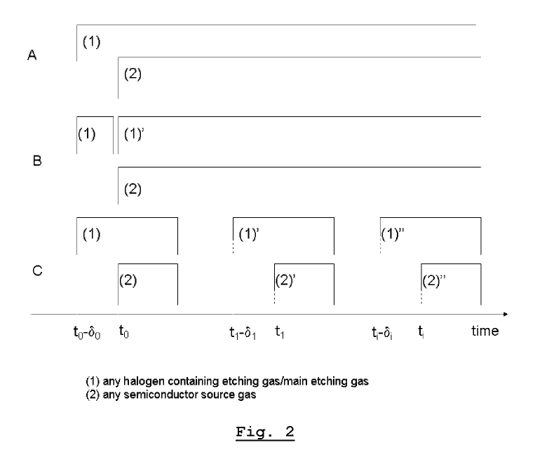

FIG. 2 is showing that the in situ HCl pre-treatment is performed immediately prior to the injection of at least one semiconductor source gas. According to one embodiment, the injection of the etching gas (HCl) starts with a time interval 60 before the injection of the at least one semiconductor source gas (t0).

According to one embodiment described in FIG. 2A, the injection of the etching gas (HCl) continues without interruption after the injection of the at least one semiconductor source gas.

According to another embodiment described in FIG. 2B, the injection of the etching gas (HCl) starts with a time interval 60 before the injection of the at least one semiconductor source gas (t0) but is then stopped and resumed with the injection of the at least one semiconductor source gas.

In the case of FIG. 2(B) the deposition temperature of the epitaxial process is lower than the in situ pre-treatment temperature to prevent the desorption of the halogen species and maintain the passivation effect.

FIG. 2C is describing the case of multiple processes (n) deposition wherein the injection of the etching gas (HCl) starts every time with a time interval δi before the injection of the at least one semiconductor source gas (ti, i=0−n). In the case of FIG. 2(C) the deposition process (i) can start immediately after the deposition process (i−1) has been finished.

The temperature of injecting the halogen containing etching gas during processes (1), (1)′ or (1)″ compared to the temperature of injecting any semiconductor source gas during processes (2), (2)′ or (2)″ may be identical or different, higher or lower.

The halogen containing etching gasses during processes (1), (1)′ and (1)″ may be identical or different, higher or lower, as well as the semiconductor source gasses during processes (2), (2)′ and (2)″.

During the injection of any semiconductor source gas during processes (2), (2)′ or (2)″, the gas during processes (1), (1)′ or (1)″ is serving as main etching gas.

In one embodiment, the in situ (HCl) pre-treatment described in processes (1), (1)′ and (1)″ corresponding to process IV of FIG. 1 may be performed at a temperature between about 500-900° C., more preferred between about 500-850° C. and even more preferred between about 550-750° C.

In one embodiment, the temperature of the in situ (HCl) pre-treatment described in processes (1), (1)′ and (1)″ corresponding to process IV of FIG. 1 should be lower than about 900° C. to prevent the desorption of the Cl-passivating species.

In one embodiment, the in situ (HCl) pre-treatment described in processes (1), (1)′ and (1)″ corresponding to process IV of FIG. 1 has a duration of at least about 30 seconds and is preferably comprised between about 1 and 10 minutes, more preferably between about 1 and 8 minutes, and even more preferably between about 2 and 4 minutes.

In another embodiment, the minimum duration of the in situ (HCl) pre-treatment described in processes (1), (1)′ and (1)″ corresponding to process IV of FIG. 1 is at least 1 second and preferably at least 1 minute.

The amount of etching required during the in situ pretreatment is less then or equivalent to the etching of about 0.5 Å-2 Å of semiconductor material, which is compatible with the most advanced process flow.

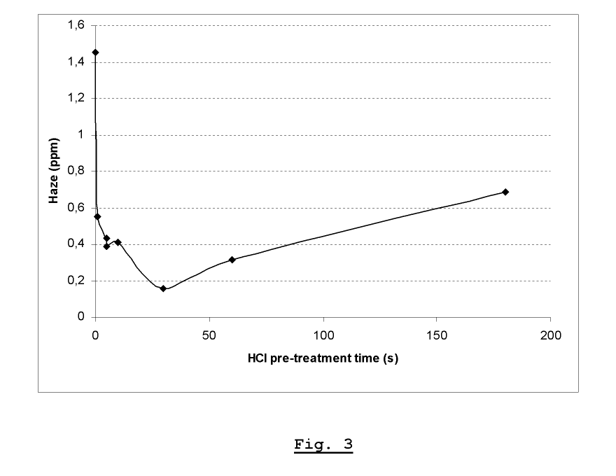

Table 2 and FIG. 3 are showing that an HCl pre-treatment (performed on diluted HF treated nitride surfaces) of 1 second already leads to an improvement of the initial haze value of the surface (being the measure of the number of nuclei with a diameter smaller than about 50 nm formed on the nitride surface upon a short deposition with dichlorosilane (DCS)). The haze value is further improving with increasing pre-treatment time, the lowest value being obtained after about 30 seconds. Increasing the HCl flow (for a given pre-treatment time) also improves the haze value.

TABLE 2
Measurement of the haze (reflecting number of nuclei
with diameter smaller than 50 nm) according to different
HCl in situ pre-treatment times.

| HCl pre- | | | |
|---|---|---|---|
| treatment time | | | |
| (s) | HCl flow (sccm) | Haze (ppm) | LPD (0.100-0.150 μm) |
| 0 | 0 | 1.456 | 61471 |
| 1 | 50 | 0.553 | 202 |
| 5 | 50 | 0.431 | 186 |
| 5 | 100 | 0.388 | 374 |
| 10 | 50 | 0.409 | 396 |
| 30 | 50 | 0.156 | 399 |
| 60 | 50 | 0.316 | 1984 |
| 180 | 50 | 0.685 | 2769 |

The beneficial effect obtained can be explained either (1) by the fact that Cl passivates the surface dangling bonds present on the nitride surface after removing a very thin oxide layer by diluted HF or (2) by the fact that diluted HF leaves a Si-rich surface by preferentially etching the N; while the in situ HCl treatment etches the superfluous Si and restores the surface stoichiometry.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A method of producing a semiconductor device using a selective epitaxial growth (SEG) process comprising:
providing a semiconductor substrate;
forming a pattern of an insulation material on the semiconductor substrate, thereby defining a covered and non covered surface;
cleaning the covered and non covered surface of the substrate having the insulating pattern defined;
loading the substrate with the insulating pattern into a reaction chamber of an epitaxial reactor;
performing a selective epitaxial growth with at least one semiconductor source gas and at least one first carrier gas injected in the reaction chamber of the epitaxial reactor; and
prior to the selective epitaxial growth process, providing an in situ pre-treatment to the surface of the substrate in the reaction chamber with the injection of a halogen containing etching gas with a second carrier gas.

2. The method according to claim 1, wherein the semiconductor substrate is selected from the following group: a single crystalline silicon substrate, a single crystalline germanium substrate, a single crystalline silicon germanium substrate, a single crystalline silicon germanium carbide substrate, and a single crystalline silicon carbide substrate or a silicon-on-insulator (SOI) substrate.

3. The method according to claim 1, wherein the insulation material is a dielectric material, preferably silicon dioxide (SiO2) or silicon nitride (Si3N4).

4. The method according to claim 1, wherein the cleaning process comprises a wet clean treatment and/or a wet etch treatment.

5. The method according to claim 1, wherein the main semiconductor source gas is selected from the following group: a silicon source gas, a germanium source gas, a silicon germanium source gas, a III/V source gas, a carbon source gas or a source gas selected from the group of germyl-silane gasses or mixtures thereof.

6. The method according to claim 1, wherein the first and/or second carrier gasses is a H2 gas or an inert gas.

7. The method according to claim 1, wherein the halogen containing etching gas is selected from the following group: a HCl gas, a Cl2 gas, a diluted HCl gas or a diluted Cl2 gas.

8. The method according to claim 7, wherein the diluted HCl gas is a mixture of HCl and H2 gas or a mixture of HCl and an inert gas.

9. The method according to claim 7, wherein the diluted Cl2 gas is a mixture of Cl2 and H2 gas or a mixture of Cl2 and an inert gas.

10. The method according to claim 1, wherein the injection of the halogen containing etching gas is at least once performed prior to the injection of the at least one semiconductor source gas, and wherein the injection of the halogen containing etching gas is continued without interruption while performing the injection of the at least one semiconductor source gas.

11. The method according to claim 1, wherein the injection of the halogen containing etching gas is at least once performed prior to the injection of the at least one semiconductor source gas, and wherein the injection of the halogen containing etching gas is stopped and resumed with performing the injection of the at least one semiconductor source gas.

12. The method according to claim 10, wherein both the injection of the at least one semiconductor source gas and the injection of the halogen containing etching gas are performed repeatedly.

13. The method according to claim 1, further comprising an in situ H2 thermal anneal prior to the in situ pre-treatment with the halogen containing etching gas.

14. The method according to claim 13, wherein the temperature of the in situ H2 thermal anneal is higher than the temperature of the in situ pre-treatment with the halogen containing etching gas.

15. The method according to claim 1, wherein the in situ pre-treatment with the halogen containing etching gas is performed at a temperature range between about 500° C. and 900° C. and preferably between about 550° C. and 750° C.

16. The method according to claim 1, wherein the in situ pre-treatment with the halogen containing etching gas is no shorter than 1 second.

17. The method according to claim 1, wherein the duration of the in situ pre-treatment with the halogen containing etching gas is at least 30 seconds and preferably at least 1 minute.

18. The method according to claim 1, wherein the in situ pre-treatment with the halogen containing etching gas is performed during a period of time ranged between 1 and 10 minutes, preferably between 1 and 8 minutes, and more preferably between 2 and 4 minutes.

19. The method according to claim 1, wherein the amount of etching required during the in situ pre-treatment with the halogen containing etching gas is less than or equivalent to the etching of about 0.5 to 10 Å of semiconductor material.

20. A method of producing a semiconductor device comprising:
applying an in situ pre-treatment to a surface of a substrate in a reaction chamber of an epitaxial reactor injected with at least a halogen containing etching gas; and
after the in situ pre-treatment, performing a selective epitaxial growth on the surface of the substrate with at least one semiconductor source gas injected in the reaction chamber.
